(19) United States
(12) Patent Application Publication
(10) Pub. No.: US 2008/0258834 A1
(43) Pub. Date: Oct. 23, 2008

(54) PULSE WIDTH MODULATION CIRCUIT

(75) Inventors: CHEN-FAN TANG, TAIPEI CITY (TW); CHENG-CHIH WANG, HSINCHU COUNTY (TW); JONG-PING LEE, HSINCHU CITY (TW); YI-CHE LIN, TAIPEI COUNTY (TW); LIAN-CHENG TSAI, HSINCHU (TW); GUAN-HONG CHOU, KAOHSIUNG CITY (TW)

Correspondence Address: J C PATENTS, INC., 4 VENTURE, SUITE 250, IRVINE, CA, 92618, US

(73) Assignee: WINBOND ELECTRONICS CORP., HSINCHU (TW)

(21) Appl. No.: 11/737,529

(22) Filed: Apr. 19, 2007

(51) Int. Cl. H03K 7/08; H02H 3/08

(52) U.S. Cl. 332/109; 361/79

(57) ABSTRACT

A pulse width modulation (PWM) circuit includes a turn on/off switch and a PWM controller. The first terminal of the turn on/off switch is coupled to a turn off voltage. The control terminal of the turn on/off switch receives a turn on/off signal to decide whether the circuit between the first terminal and the second terminal of the turn on/off switch is turned on or not. The PWM controller includes a PWM pin and a turn on/off device. The PWM pin is coupled to the second terminal of the turn on/off switch to output a PWM signal. The turn on/off device is coupled to the PWM pin to decide the turn on/off of the PWM controller according to a signal swing state of the PWM pin.

### BACKGROUND OF THE INVENTION

1. Field of the Invention

The present invention relates to a pulse width modulation (PWM) circuit. More particularly, the present invention relates to a PWM circuit capable of increasing utilization of a PWM controller pin and increasing over-current protection accuracy.

2. Description of Related Art

PWM technique is usually used in a power converter for providing a stable output voltage to an electronic device. FIG. 1 is a circuit diagram of a buck converter with a conventional PWM circuit. As shown in FIG. 1, the PWM circuit includes a PWM controller 12 and switches 141, 142. The PWM controller 12 includes comparators 121, 122, a current source 123, drivers 124, 125, and a plurality of pins 131-138.

After the PWM circuit is turned on, an enable voltage Ven is supplied to a pin 138 of the PWM controller 12 so as to turn on the PWM controller 12. However, as for the above PWM circuit of FIG. 1, an additional pin 138 must be used to receive the enable voltage Ven, thus causing a waste of the pin of the PWM controller. Additionally, the pin 131 is directly coupled to an input voltage Vin, so the circuit coupled to the pin 131 requires for a high voltage resistance element, which causes an increase of the cost and the design complexity of the circuit.

FIG. 2 is a circuit diagram of a buck converter with another conventional PWM circuit. As shown in FIG. 2, the PWM circuit includes a PWM controller 22 and switches 241, 242, and 211. The PWM controller 22 includes a plurality of comparators 221, 222, and 226, drivers 224, 225, a dual power sensor 228, a current source 223, and a plurality of pins 231-238. Comparing FIG. 1 with FIG. 2, the difference between the circuits of FIGS. 2 and 1 lies in that the PWM controller 22 of FIG. 2 only uses the pin 231 and the switch 211 to simultaneously achieve three functions, such as over-current protection, turn on detection, and input voltage detection.

The actions are described as follows. The comparator 226 is used to compare the voltage of the pin 231 with a reference voltage Vref3, when the voltage of the pin 231 is greater than the reference voltage Vref3, the PWM controller 22 is enabled. The comparator 222 is used to compare a reference voltage Vref2 and the voltage of the pin 231, when the reference voltage Vref2 is greater than the voltage of the pin 231, the over-current protection function is turned on. The comparator 221 is used to compare the voltage of the pin 231 and a reference voltage Vref1, when the voltage of the pin 231 is greater than the reference voltage Vref1, a comparing signal is output, and the dual power sensor 228 is used to receive the comparing signal and the sensing power voltage Vcc, thereby determining whether the input voltage Vin is turned on or not.

However, the method has the defects that the pin 231 is quite sensitive to parasitic capacitance. During the protection of the over-current, the action is similar to that of a resistor-capacitor charge-discharge circuit. Here, the parasitic capacitance of the switch 211 may seriously affect the accuracy of the over-current protection, thus increasing the risk of the damage to the system.

### SUMMARY OF THE INVENTION

Accordingly, the present invention is directed to a PWM circuit, which includes a first turn on/off switch and a PWM controller. A first terminal of the first turn on/off switch is coupled to a turn off voltage, and a control terminal receives a turn on/off signal for deciding whether a circuit between the first terminal and the second terminal is turned on or not. The PWM controller includes a first PWM pin and a turn on/off device. The first PWM pin is coupled to the second terminal of the first turn on/off switch for outputting a first PWM signal. The turn on/off device is coupled to the first PWM pin, so as to decide the turn on/off of the PWM controller according to a signal swing state of the first PWM pin.

The PWM circuit of the present invention adopts the first turn on/off switch to decide whether the first turn on/off switch is turned on or not according to the turn on/off signal. The turn on/off device of the PWM controller decides the turn on/off of the PWM controller according to the signal swing state of the first PWM pin of the PWM controller, so as to save the pin of the PWM controller and to increase the protection accuracy of the over-current protection circuit and the selectivity of the switch element, thereby improving the security of the system.

In order to the make aforementioned and other objects, features and advantages of the present invention comprehensible, preferred embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a buck converter with a conventional PWM circuit.

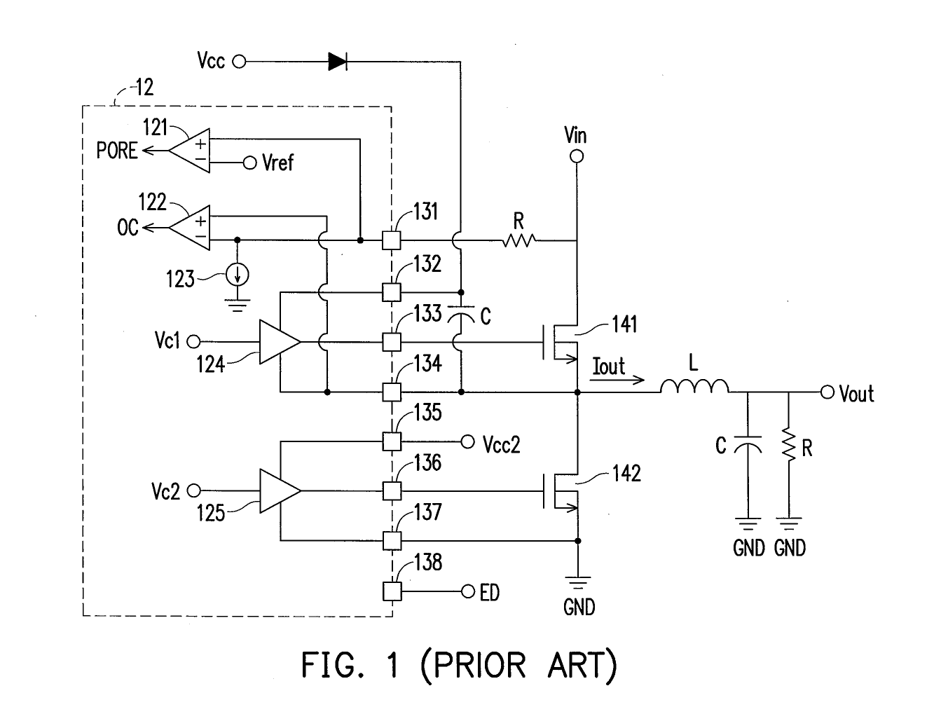

FIG. 2 is a circuit diagram of a buck converter with another conventional PWM circuit.

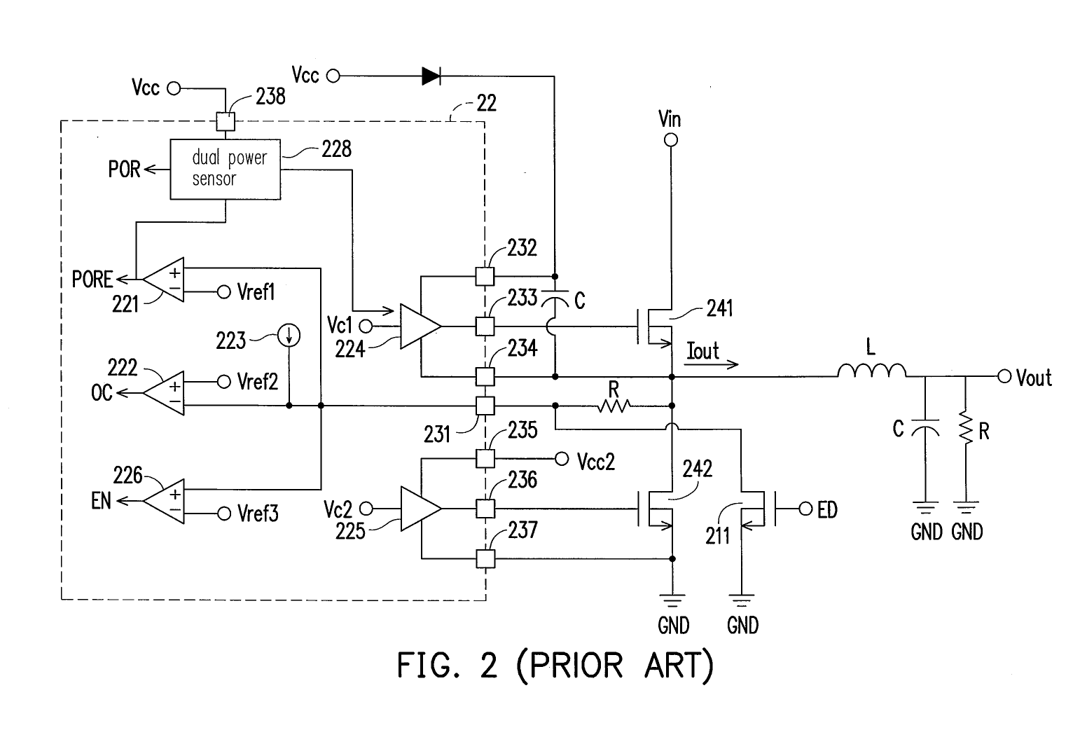

FIG. 3 is a circuit diagram of a PWM circuit according to an embodiment of the present invention.

FIG. 4 is a circuit diagram of another PWM circuit according to an embodiment of the present invention.

FIG. 5 is a circuit diagram of still another PWM circuit according to an embodiment of the present invention.

### DESCRIPTION OF EMBODIMENTS

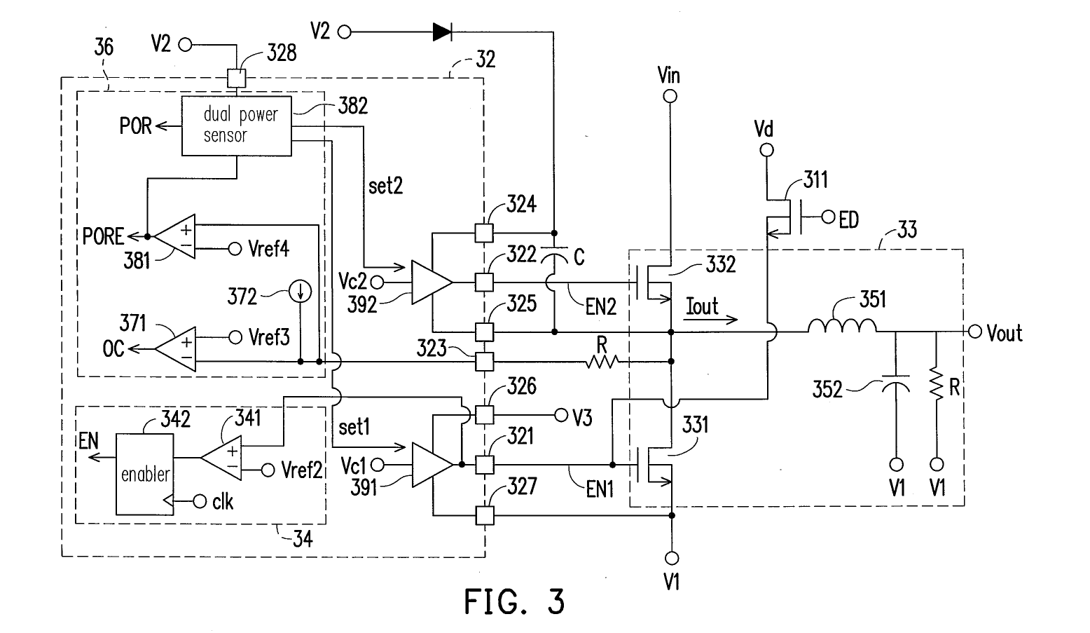

FIG. 3 is a circuit diagram of a PWM circuit according to an embodiment of the present invention. As shown in FIG. 3, the PWM circuit includes a first turn on/off switch 311, a PWM controller 32, and a power converter 33. The power converter 33 is a buck converter, which includes a first switch 331, a second switch 332, an inductor 351, and a capacitor 352. The PWM controller 32 includes a first PWM pin 321, a second PWM pin 322, a versatile pin 323, a turn on/off device 34, and a protection device 36. The turn on/off device 34 includes a preliminary enable comparator 341 and an enabler 342. The protection device 36 includes a current source 372, an over-current protection comparator 371, a power sensing comparator 381, and a dual power sensor 382.

The turn on/off device 34 decides the turn on/off of the PWM controller 32 according to the signal swing state of the first PWM pin 321. In this embodiment, the turn on/off device 34 continuously senses whether the voltage of the first PWM pin 321 is maintained at a turn off voltage Vd in a default time, so as to decide whether to turn off the PWM controller 32. The protection device 36 senses the voltage of the versatile pin 323, so as to decide whether the PWM circuit 32 enters the protection mode or not. In this embodiment, the protection device 36 continuously senses whether the signal of the versatile pin 323 is smaller than the reference voltage Vref3, so as to decide whether the modulation controller 32 is made to temporarily turn off the power converter 33, such that the PWM circuit of this embodiment enters the protection mode and is in the stand-by state.

For example, it is assumed that the turn off voltage Vd is at a high voltage level, when the turn on/off signal ED is at a high voltage level, the first turn on/off switch 311 is turned on, and the signal of the first PWM pin 321 is raised to the high voltage level. Here, the preliminary enable comparator 341 compares the voltage of the first PWM pin 321 and a second reference voltage Vref2, and the voltage of the first PWM pin 321 at the high voltage level is greater than the second reference voltage Vref2, the first comparator 341 outputs a preliminary enable signal PEN at the first logic voltage level. The enabler 342 receives a preliminary enable signal PEN at the first logic voltage level, so as to start accumulating an accumulation value built-in an enabler 342 according to a clock signal clk.

If the turn on/off signal ED is continuously maintained at the high voltage level, the preliminary enable signal PEN is continuously maintained at the first logic voltage level, the enabler 342 continuously accumulates the accumulation value until the accumulation value is greater than a default value. Then, an enable signal EN is output, and the enable signal EN controls the PWM controller 32 to turn off.

The turn off voltage Vd can also be the low voltage level. The simplest modification method adds an inverter in the turn on/off device 34. The signal of the first PWM pin 321 after being inverted is maintained to be greater than the second reference voltage Vref2 for a time exceeding the default time, and then the turn on/off device 34 turns off the PWM controller 32.

Similarly, the design of the common voltage V1 and V2 is not limited, and the embodiment of the present invention can be modified for different applications as long as the suitable reference voltage design and the comparator design are used.

When the PWM circuit works, the protection device 36 continuously senses the voltage of the versatile pin 323. When the voltage of the versatile pin 323 is smaller than a third reference voltage Vref3, the over-current protection comparator 371 determines that the load current lout is too large, and a current protection comparing signal OC is output to turn off the first switch 331 and the second switch 332, so as to prevent the load current lout becoming too large.

The protection device 36 can also perform power sensing. The power sensing comparator 381 is used to compare the voltage of the versatile pin 323 and a fourth reference voltage Vref4. When the voltage of the versatile pin 323 is greater than the fourth reference voltage Vref4, a power sensing comparing signal PORE is output. The dual power sensor 382 can sense whether a second common voltage V2 is turned on or not, and receive the power sensing comparing signal PORE and sense whether the input voltage Vin is turned on or not, so as to make sure whether the PWM controller 32 operates normally or not. Then, the dual power sensor 382 outputs a first control signal set1 to the first driver 391 to turn off the first switch 331, outputs a second control signal set2 to the second driver 392 to turn on the second switch 332, and outputs a third control signal POR to the PWM controller 32.

After the PWM controller 32 receives the third control signal POR, a first drive signal Vc1 and a second drive signal Vc2 are generated. The first driver 391 receives the first drive signal Vc1, and outputs a first PWM control signal EN1 through the first PWM pin 321, so as to control the turn on/off of the first switch 331. The second driver 392 receives the second drive signal Vc2, and outputs a second PWM control signal EN2 through the second PWM pin 322, so as to control the turn on/off of the second switch 332.

The first PWM control signal EN1 and the second PWM control signal EN2 are periodic signals, and have opposite phases. Therefore, it is possible to periodically control the turn on/off between the first switch 331 and the second switch 332, so as to control the magnitude of the output voltage Vout, thus finishing the buck conversion function of the PWM circuit of this embodiment.

Those of ordinary skill in the art should know that different manufacturers have different design methods of the PWM controller 32 and the power converter 33, so the application of the present invention is not limited to the possible form. In other words, whether the first turn on/off switch 311 is turned on or not according to the turn on/off signal ED, and the turn on/off device 34 of the PWM controller 32 decides whether the PWM controller 32 is turned on or not according to the signal swing state of the first PWM pin 321 of the PWM controller 32, it conforms to the spirit of the present invention.

In the following description, several embodiments are illustrated, such that those of ordinary skills in the art can easily implement the present invention.

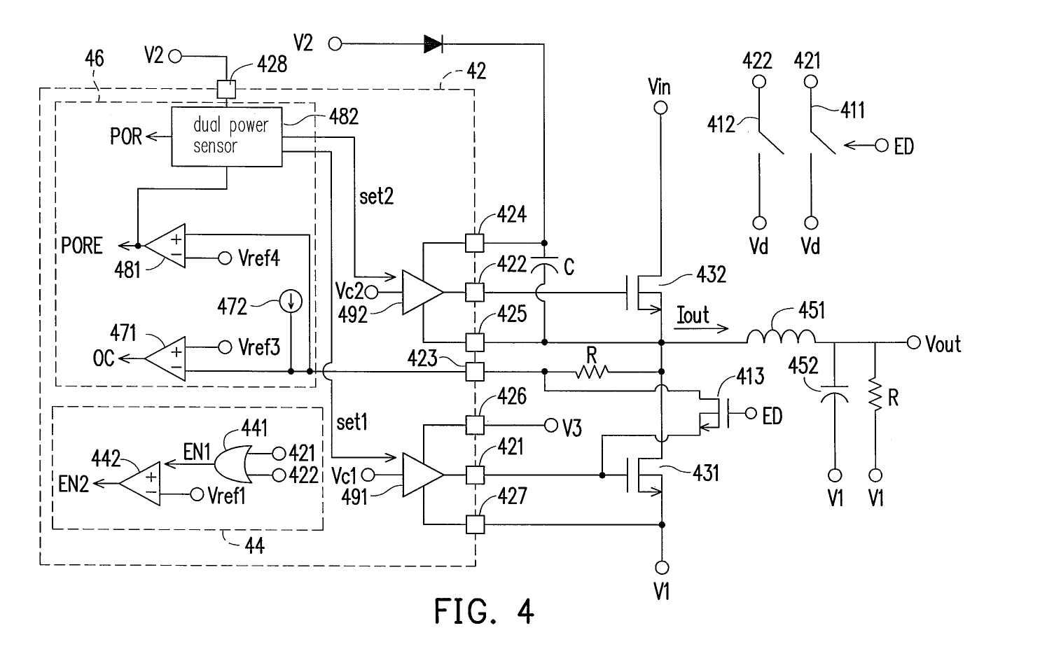

FIG. 4 is a circuit diagram of another PWM circuit according to an embodiment of the present invention. As shown in FIG. 4, the PWM circuit includes a first turn on/off switch 411, a second turn on/off switch 412, a third turn on/off switch 413, a PWM controller 42, and a power converter of the embodiment of the present invention. The power converter of the embodiment of the present invention is a buck converter, which includes a first switch 431, a second switch 432, an inductor 451, and a capacitor 452. The PWM controller 42 includes a first PWM pin 421, a second PWM pin 422, a versatile pin 423, a turn on/off device 44, and a protection device 46. The turn on/off device 44 includes a logic circuit 441 and a logic circuit comparator 442. The protection device 46 includes a current source 472, an over-current protection comparator 471, a power sensing comparator 481, and a dual power sensor 482.

Different from FIG. 3, FIG. 4 uses a different manner to realize the turn on/off device 44. In the embodiment of FIG. 4, the turn on/off device 44 senses the first PWM pin 421 and the second PWM pin 422. When the signals of the first PWM pin 421 and the second PWM pin 422 are at the same voltage level, the turn on/off device 44 turns off the PWM controller 42. For example, it is assumed that the turn off voltage Vd is at a low voltage level, a logic default voltage level is the low voltage level, and the logic circuit 441 is a logic OR gate. After a turn on/off signal ED turns on the first turn on/off switch 411 and the second turn on/off switch 412, the signals of the first PWM pin 421 and the second PWM pin 422 are raised to the low voltage level. When the signals of the first PWM pin 421 and the second PWM pin 422 are at the low voltage level, the logic circuit 441 outputs an enable signal EN1 at the low voltage level. At this time, the enable signal EN1 is smaller than a first reference voltage Vref1, such that the logic circuit comparator 442 outputs a compare signal EN2 at the logic low voltage level. As the logic circuit comparator 442 outputs the compare signal EN2, the PWM controller 42 is turned off. The remaining operations are the same as those of the embodiment of FIG. 3, so the details will not be described herein again.

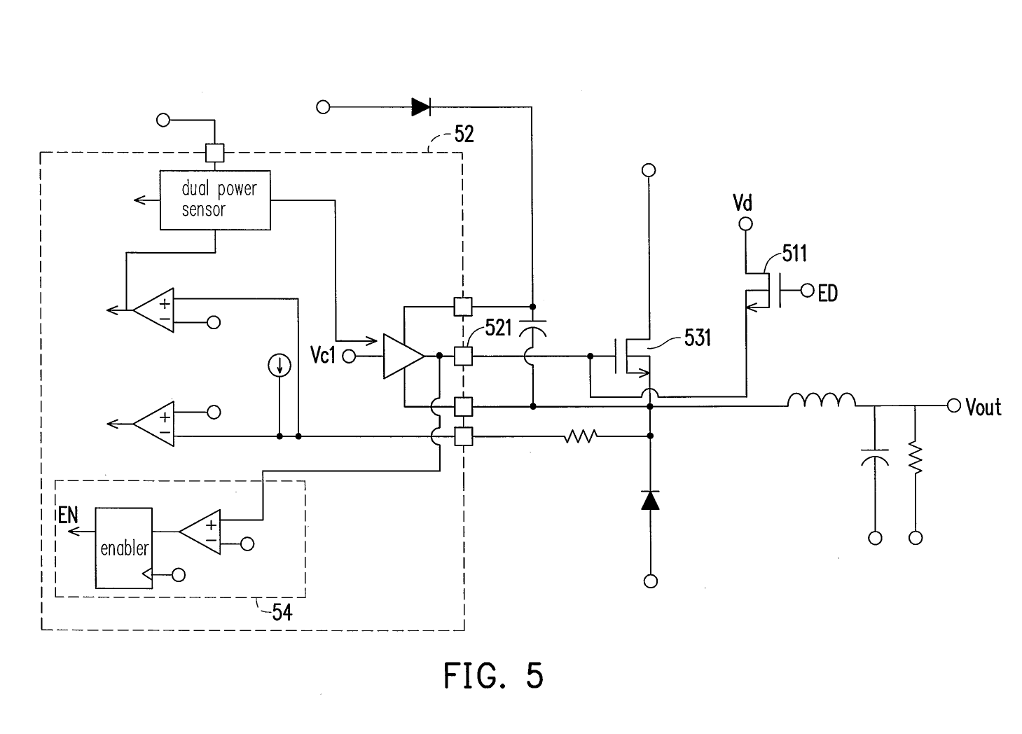

FIG. 5 is a circuit diagram of still another PWM circuit according to an embodiment of the present invention. Different from FIG. 3, the power converter applied to the PWM circuit of FIG. 5 only uses a first switch 531. When the PWM circuit of this embodiment operates, the PWM controller 52 controls the voltage level of the first PWM pin 521 through the first drive signal Vc1 and decides whether the first switch 531 is turned on/off, so as to control the output voltage Vout of the power converter using this embodiment. After the turn on/off signal ED turns on the first turn on/off switch 511, the voltage level of the first PWM pin 521 is raised to the turn off voltage Vd. The turn on/off device 54 detects that the voltage level on the PWM pin 521 is maintained at the turn off voltage Vd for a time exceeding a default time, and the PWM controller 52 is turned off.

The operation details and other elements not mentioned in the embodiment of FIG. 5 are the same as those of the embodiments of FIGS. 3 and 4, so the details will not be described herein again. In addition, in the embodiment, the so-called turn off PWM controller can totally turn off all the functions of the PWM controller, or can turn off a part of the functions of the PWM controller.

It will be apparent to those skilled in the art that various modifications and variations can be made to the structure of the present invention without departing from the scope or spirit of the invention. In view of the foregoing it is intended that the present invention cover modifications and variations of this invention provided they fall within the scope of the following claims and their equivalents.

What is claimed is:

1. A pulse width modulation (PWM) circuit, comprising:
a first turn on/off switch, having a first terminal coupled to a turn off voltage and a control terminal receiving a turn on/off signal, for deciding whether a circuit between the first terminal and a second terminal is turned on or not; and
a PWM controller, comprising:
a first PWM pin, coupled to the second terminal of the first turn on/off switch, for outputting a first PWM signal; and
a turn on/off device, coupled to the first PWM pin, for deciding the turn on/off of the PWM controller according to a signal swing state of the first PWM pin.

2. The PWM circuit as claimed in claim 1, wherein the PWM controller is used to control a first switch of a power converter, the first switch comprises a first terminal, a second terminal, and a control terminal, the control terminal of the first switch is coupled to the first PWM pin, the first terminal of the first switch is coupled to a first common voltage, and the first switch decides whether the circuit between the first terminal and the second terminal is turned on or not according to the first PWM signal.

3. The PWM circuit as claimed in claim 2, wherein the power converter comprises a second switch which has a first terminal receiving an input voltage, a second terminal coupled to an output terminal of the power converter and the second terminal of the first switch, and a control terminal receiving a second PWM signal, and the PWM controller further comprises a second PWM pin for outputting the second PWM signal.

4. The PWM circuit as claimed in claim 3, further comprising:
a second turn on/off switch, having a first terminal coupled to the turn off voltage, a second terminal coupled to the second PWM pin, and a control terminal receiving the turn on/off signal, for deciding whether a circuit between the first terminal and the second terminal is turned on or not;
wherein the turn on/off device is further coupled to the second PWM pin, for deciding the turn on/off of the PWM controller according to the signals of the first PWM pin and the second PWM pin.

5. The PWM circuit as claimed in claim 4, wherein the turn on/off device comprises:
a logic circuit, having a first terminal receiving the voltage of the first PWM pin, and a second terminal receiving the voltage of the second PWM pin, wherein when the voltage level of the first PWM pin and the voltage level of the second PWM pin are at a logic default voltage level at the same time, an enable signal is output, so as to decide the turn on/off of the PWM controller.

6. The PWM circuit as claimed in claim 5, wherein the turn on/off device further comprises:
a logic circuit comparator, coupled to the output terminal of the logic circuit, comparing the voltage level of the enable signal and a first reference voltage, so as to decide the turn on/off of the PWM controller.

7. The PWM circuit as claimed in claim 3, wherein the power converter is a buck converter, comprising:
an inductor, coupled between the output terminal of the power converter and the second terminal of the second switch; and
a capacitor, coupled between the output terminal of the power converter and the first common voltage.

8. The PWM circuit as claimed in claim 3, wherein the second PWM signal and the first PWM signal have opposite phases.

9. The PWM circuit as claimed in claim 1, wherein the turn on/off device comprises:
a preliminary enable comparator, having a first input terminal coupled to the PWM pin and a second input terminal coupled to a second reference voltage, wherein when the voltage level of the PWM pin is greater than the second reference voltage, a preliminary enable signal is output; and
an enabler, having an input terminal coupled to the output terminal of the preliminary enable comparator and receiving the preliminary enable signal, wherein when the enable time of the preliminary enable signal is greater than a default time, an enable signal is output, so as to decide the turn on/off of the PWM controller.

10. The PWM circuit as claimed in claim 9, wherein the enabler is a counter that has an input terminal coupled to the output terminal of the preliminary enable comparator and a clock input terminal receiving a clock signal, wherein when the preliminary enable signal is in a first logic state, the counter accumulates an accumulation value according to the clock signal, when the preliminary enable signal is in a second logic state, the counter resets the accumulation value, and when the accumulation value is greater than a default value, the enable signal is output and enabled.

11. The PWM circuit as claimed in claim 1, wherein the turn on/off device comprises:
a preliminary enable comparator, having a first input terminal coupled to the PWM pin and a second input terminal coupled to a second reference voltage, wherein when the voltage level of the PWM pin is smaller than the second reference voltage, a preliminary enable signal is output; and
an enabler, having an input terminal coupled to the output terminal of the preliminary enable comparator and receiving the preliminary enable signal, wherein when the enable time of the preliminary enable signal is greater than a default time, an enable signal is output, so as to decide the turn on/off of the PWM controller.

12. The PWM circuit as claimed in claim 11, wherein the enable is a counter that has an input terminal coupled to the output terminal of the preliminary enable comparator and a clock input terminal receiving a clock signal, wherein when the preliminary enable signal is in a first logic state, the counter accumulates an accumulation value according to the clock signal, when the preliminary enable signal is in a second logic state, the counter resets the accumulation value, and when the accumulation value is greater than a default value, the enable signal is output and enabled.

13. The PWM circuit as claimed in claim 1, wherein the PWM controller comprises:
a versatile pin, coupled to the output terminal; and
a protection device, coupled to the versatile pin, for sensing the voltage of the versatile pin, and deciding whether PWM circuit enters the protection mode or not.

14. The PWM circuit as claimed in claim 13, wherein the protection device comprises:
a current source, coupled to the versatile pin, and supplying a comparing current; and
an over-current protection comparator, having a first input terminal coupled to a third reference voltage and a second input terminal coupled to the versatile pin, wherein when the voltage of the versatile pin is smaller than the third reference voltage, an over-current protection comparing signal is output to the PWM controller, such that the PWM controller turns off the first switch and the second switch, and the PWM circuit enters the protection mode.

15. The PWM circuit as claimed in claim 13, wherein the protection device further comprises:
a power sensing comparator, having an first input terminal coupled to the versatile pin and a second input terminal coupled to a fourth reference voltage, wherein when the voltage of the versatile pin is greater than the fourth reference voltage, a power sensing comparing signal is output.

16. The PWM circuit as claimed in claim 13, wherein the protection device further comprises:
a dual power sensor, having a first sensing terminal coupled to a second common voltage and a second sensing terminal coupled to the output terminal of the power sensing comparator, the dual power sensor sensing the second common voltage and senses the input voltage according to the power sensing comparing signal, so as to output a plurality of control signals.

17. The PWM circuit as claimed in claim 13, further comprising:
a third turn on/off switch, having a first terminal coupled to the versatile pin, a second terminal coupled to the first PWM pin, and a control terminal receiving the turn on/off signal, for deciding whether a circuit between the first terminal and the second terminal is turned on or not.
